(19) United States
(12) Patent Application Publication
(10) Pub. No.: US 2006/0199111 A1
(43) Pub. Date: Sep. 7, 2006

(54) Method for manufacturing semiconductor devices using a photo acid generator

(75) Inventor: Jen-Chieh Shih, Yongkang City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 11/070,396

(22) Filed: Mar. 1, 2005

(51) Int. Cl. G03F 7/00

(52) U.S. Cl. 430/327; 430/330

(57) ABSTRACT

Provided is a method for manufacturing a semiconductor device. In one example, the method includes providing a substrate, forming a photo acid generator (PAG) layer over the substrate, where the PAG layer includes at least one PAG, and forming a photoresist layer over the PAG layer.

### BACKGROUND

Semiconductor technology frequently uses a photolithography process during the creation of semiconductor devices. One factor to be considered for a photolithography process is a suitable depth of focus (DOF) window, which identifies a distance along an optical axis over which features of a semiconductor device are in focus. An effective DOF covers different variations of photoresist thickness, local substrate topology step height, wafer center and edge step height differences. Accordingly, an effective DOF enables a semiconductor device to be manufactured within specified critical dimensions (CD) without scumming (e.g., inadequate development), top loss defects, or other undesirable issues. However, certain problems may arise with respect to the DOF for a photolithography process, such as radiation dose intensity. For example, during a photolithography process, the dose intensity of the light in a defocused area is generally lower than that of a focused area, which may cause undesirable photoresist profiles.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1a illustrates a tapered photoresist profile.

FIG. 1b illustrates an undercut photoresist profile.

FIG. 1c illustrates a photoresist profile that may be produced according to one or more embodiments of the present invention.

FIGS. 2a-2d illustrate one embodiment of a partial semiconductor device during various stages of manufacture.

FIGS. 3a-3d illustrate another embodiment of a partial semiconductor device during various stages of manufacture.

FIG. 4 is a chart illustrating exemplary relationships between combinations of dose intensity and PAG intensity with respect to DOF.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

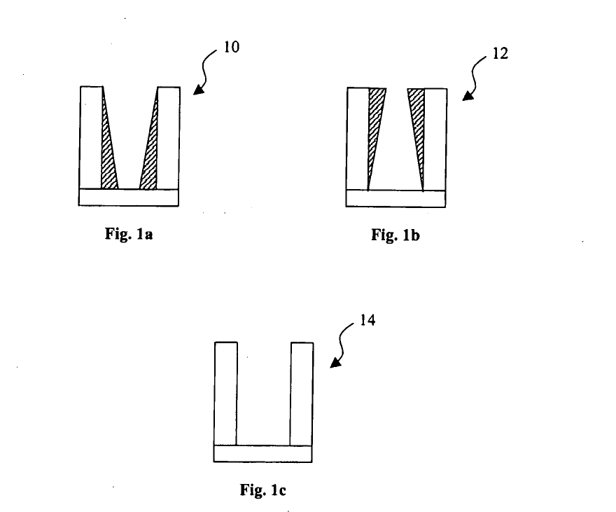

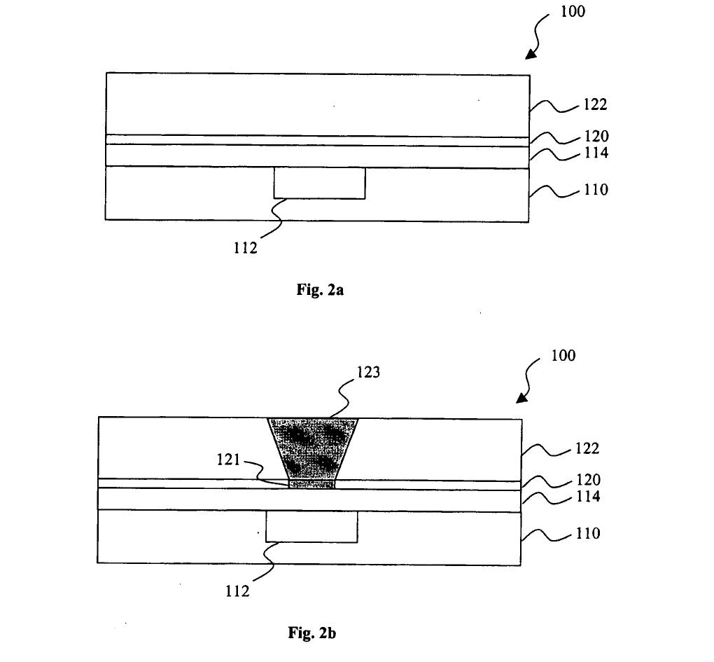

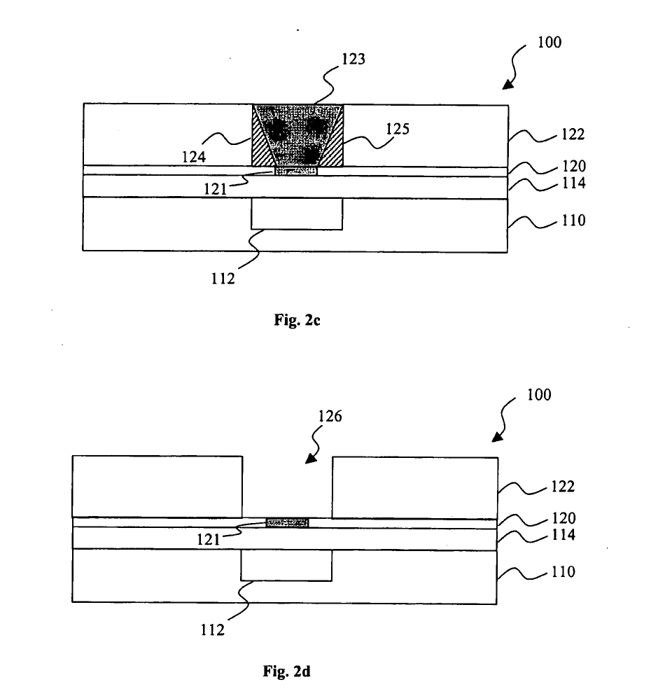

Referring to FIGS. 1a-1c, various profiles may be produced by photolithography processes having differing DOFs. For example, a limited DOF used with a resist may result in a relatively small quantity of photo acids being produced in a defocused area. Such a limited DOF may result in a tapered photoresist profile 10 (FIG. 1a) or an undercut photoresist profile 12 (FIG. 1b), as opposed to an ideal photoresist profile 14 as illustrated in FIG. 1c.

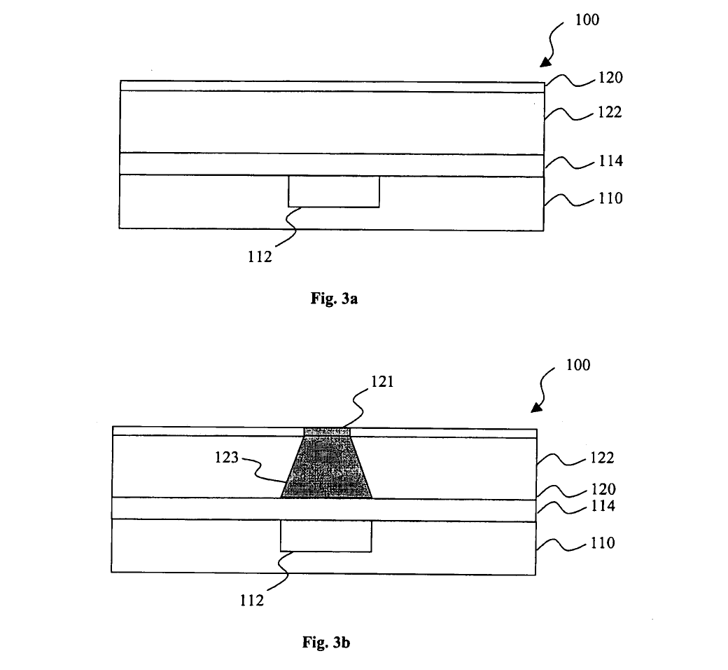

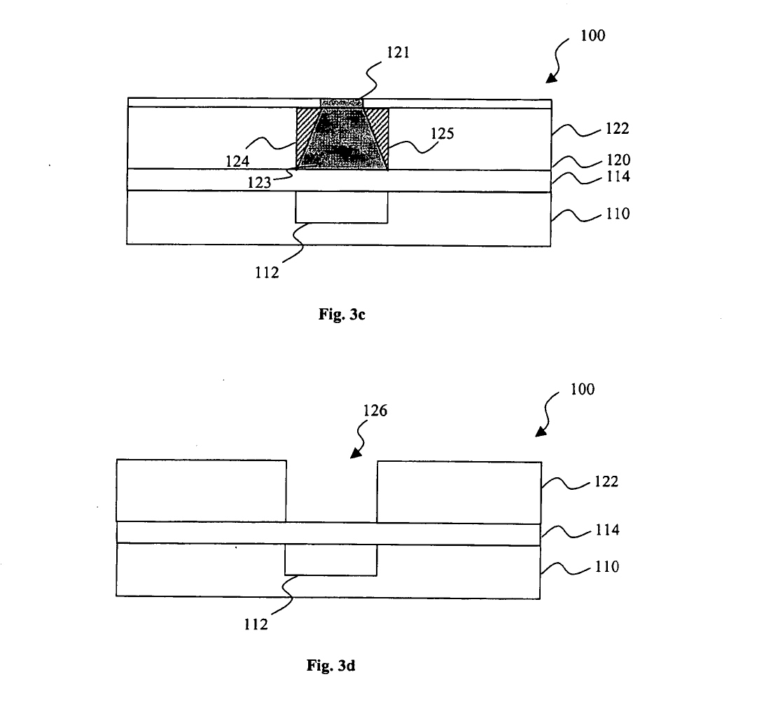

As will be described below with reference to specific examples, the profiles 10 and 12 may be minimized or avoided by increasing the quantity of photo acids in the defocused area, so that a profile similar to the photoresist profile 14 is produced. The increased quantity of photo acids in the defocused area may be accomplished using, for example, a photo acid generator (PAG) layer. In one embodiment, as will be described in connection with FIG. 2a, a layer containing one or more PAGs may be formed under a photoresist layer. In another embodiment, as will be described in connection with FIG. 3a, a layer containing one or more PAGs may be formed over a photoresist layer.

Referring now to FIG. 2a, in one embodiment, a partial semiconductor device 100 is illustrated. The device 100 includes a substrate 110, a conductive layer 112, a dielectric layer 114, a PAG layer 120, and a photoresist layer 122. The substrate 110 may include one or more insulator, conductor, and/or semiconductor layers. For example, the substrate 110 may include an elementary semiconductor, such as crystal silicon, polycrystalline silicon, amorphous silicon, and/or germanium; a compound semiconductor, such as silicon carbide and/or gallium arsenic; or an alloy semiconductor, such as SiGe, GaAsP, AlInAs, AlGaAs, and/or GaInP. Furthermore, the substrate 110 may include a bulk semiconductor, such as bulk silicon, and such a bulk semiconductor may include an epi silicon layer. It may also or alternatively include a semiconductor-on-insulator substrate, such as a silicon-on-insulator (SOI) substrate, or a thin-film transistor (TFT) substrate. The substrate 110 may also or alternatively include a multiple silicon structure or a multilayer compound semiconductor structure.

The conductive layer 112 may be formed in a recess in the substrate 110 by chemical vapor deposition (CVD), plasma-enhanced CVD (PECVD), physical vapor deposition (PVD), ionized PVD (I-PVD), atomic layer deposition (ALD), plating, and/or other processes. Chemical-mechanical planarization and/or chemical-mechanical polishing may also be employed during the formation of the conductive layer 112. For example, the conductive layer 112 may be planarized so that it is substantially coplanar with a surface of the substrate 110, as shown in FIG. 2a. In another embodiment, planarization of the conductive layer 112 may be less extensive, so that the conductive layer 112 may extend at least partially above the surface of the substrate 110. Characterizations herein of the conductive layer 112 as being formed in the substrate 110 are intended to include both of those embodiments, in addition to other alternative embodiments.

The conductive layer 112 may be a conductive feature connecting semiconductor devices, integrated circuit devices, integrated circuit components, and/or interconnects therein. The conductive layer 112 may include aluminum, aluminum alloy, copper, copper alloy, tungsten, and/or other conductive materials.

The dielectric layer 114 may be formed on the surface of the substrate 110. The dielectric layer 114 may be formed by CVD, PECVD, ALD, PVD, spin-on coating and/or other processes. The dielectric layer 114 may be an inter-metal dielectric (IMD), and may include low-k materials, silicon dioxide, polyimide, spin-on-glass (SOG), fluoride-doped silicate glass (FSG), Black Diamond® (a product of Applied Materials of Santa Clara, Calif.), Xerogel, Aerogel, amorphous fluorinated carbon, and/or other materials.

The PAG layer 120 includes at least one PAG that includes one or more components such as aryl onium salts (triarylsulfoniums or diaryliodoniums) or thiophene. The PAG may be combined with any of a variety of materials. For example, the PAG may be dissolved in a solvent, such as butanol, water, and/or any other suitable solvent. In another example, the PAG may be blended into one or more polymers, such as acrylate, methacrylate, para-hydroxy styrene, and/or any other suitable polymer, which may be developable or non-developable. In some embodiments, the PAG may include one or more ionic and/or non-ionic components. The PAG layer 120 may be deposited over the dielectric layer 114 using a variety of techniques, such as spin-on coating, PVD, chemical CVD, and/or other processes. For example, the PAG layer 120 may be sprayed over the dielectric layer 114. It is understood that the method used to form the PAG layer 120 may vary depending on the material(s) comprising the PAG layer 120.

In some embodiments, the PAG layer 120 may form a bottom anti-reflective coating (BARC) layer that absorbs light that penetrates the bottom of the photoresist layer 122. To perform the light absorption, the PAG layer 120 may include a material with a high extinction coefficient and/or considerable thickness. However, a high coefficient of the PAG layer 120 may lead to the high reflectivity of the PAG layer, which counters the effectiveness of the BARC. Accordingly, it is contemplated that the PAG layer 120 may possess a coefficient value between approximately 0.2 and 0.5, and may possess a thickness of about 200 nm. However, it is noted that other ranges of coefficient values and thickness are also contemplated by the present disclosure.

Alternatively or additionally, an index matching approach may be adopted for using the PAG layer 120 as a BARC. For example, the PAG layer 120 may include a material with a refraction index and thickness that match those of the light used for the photolithography process. In operation, once the light strikes the PAG layer 120, a portion of the light is reflected therefrom. Meanwhile, another portion of the light enters the PAG layer 120 and is transformed into a light with a shifted phase, which interferes with the first portion of the light that is reflected from the PAG layer 120, resulting in the reduction of the light reflectivity.

The photoresist layer 122 may be formed over the PAG layer 120 using a process such as spin-on coating. For example, a photoresist solution may be dispensed onto the surface of the PAG layer 120, and the device 100 may be spun rapidly until the photoresist solution is almost dry. It is understood that the photoresist layer 122 may be a chemically amplified resist that employs acid catalysis. In that case, the photoresist layer 122 may be formulated by dissolving an acid sensitive polymer in a casting solution.

Following the deposition of the photoresist layer 122, the partial semiconductor device 100 may undergo a soft-bake (also known as pre-bake or post-apply bake) process to prepare for the next step of exposure.

Referring to FIG. 2b, the partial semiconductor device 100 is exposed to radiation during an exposure process to create a latent image in the photoresist layer 122. In the present example, the exposure results in a tapered profile (indicated by reference numeral 123) in the resist layer 122. In addition to exposing the tapered area 123, the exposing process exposes a portion (indicated by reference numeral 121) of the PAG layer 120 and generates photo acid therein. It is understood that the actual dimensions of the portion 121 may vary from those illustrated (e.g., the portion 121 may be tapered, etc.).

Referring to FIG. 2c, in furtherance of the example, a post-exposure baking process is preformed on the device 100 after the exposure process. During the post-exposure baking process, the photo acids generated from the PAG layer portion 121 are diffused thorough the photoresist (particularly in photoresist portions 124 and 125) and react with the photoresist to de-protect the photoresist (e.g., to remove the photoresist's protecting group) through a catalytic reaction initiated by the thermal baking process.

Referring to FIG. 2d, after the post-exposure baking, the baked device 100 undergoes a development process to develop the photoresist layer 122. Due to the reaction caused by the diffused acids from the PAG layer portion 121, the development process results in a photoresist profile 126 in which the tapered sidewalls of FIG. 2b are minimized or eliminated. Accordingly, the PAG layer 120 results in an improved DOF. In one example, the enhanced DOF may be approximately 0.15 (as opposed to 0.05 in the absence of the PAG layer 120).

Although additional manufacturing steps may be performed after those illustrated in FIG. 2d, such steps are similar or identical to those known in the art, and they will not be further described herein.

Referring now to FIG. 3a, in another embodiment, a partial semiconductor device 100 is illustrated. The device 100 includes a substrate 110, a conductive layer 112, a dielectric layer 114, a photoresist layer 122, and a PAG layer 120 overlaying the photoresist layer. The substrate 110 may include one or more insulator, conductor, and/or semiconductor layers. For example, the substrate 110 may include an elementary semiconductor, such as crystal silicon, polycrystalline silicon, amorphous silicon, and/or germanium; a compound semiconductor, such as silicon carbide and/or gallium arsenic; or an alloy semiconductor, such as SiGe, GaAsP, AlInAs, AlGaAs, and/or GaInP. Furthermore, the substrate 110 may include a bulk semiconductor, such as bulk silicon, and such a bulk semiconductor may include an epi silicon layer. It may also or alternatively include a semiconductor-on-insulator substrate, such as a silicon-on-insulator (SOI) substrate, or a thin-film transistor (TFT) substrate. The substrate 110 may also or alternatively include a multiple silicon structure or a multilayer compound semiconductor structure.

The conductive layer 112 may be formed in a recess in the substrate 110 by chemical vapor deposition (CVD), plasma-enhanced CVD (PECVD), physical vapor deposition (PVD), ionized PVD (I-PVD), atomic layer deposition (ALD), plating, and/or other processes. Chemical-mechanical planarization and/or chemical-mechanical polishing may also be employed during the formation of the conductive layer 112. For example, the conductive layer 112 may be planarized so that it is substantially coplanar with a surface of the substrate 110, as shown in FIG. 2a. In another embodiment, planarization of the conductive layer 112 may be less extensive, so that the conductive layer 112 may extend at least partially above the surface of the substrate 110. Characterizations herein of the conductive layer 112 as being formed in the substrate 110 are intended to include both of those embodiments, in addition to other alternative embodiments.

The conductive layer 112 may be a conductive feature connecting semiconductor devices, integrated circuit devices, integrated circuit components, and/or interconnects therein. The conductive layer 112 may include aluminum, aluminum alloy, copper, copper alloy, tungsten, and/or other conductive materials.

The dielectric layer 114 may be formed on the surface of the substrate 110. The dielectric layer 114 may be formed by CVD, PECVD, ALD, PVD, spin-on coating and/or other processes. The dielectric layer 114 may be an inter-metal dielectric (IMD), and may include low-k materials, silicon dioxide, polyimide, spin-on-glass (SOG), fluoride-doped silicate glass (FSG), Black Diamond® (a product of Applied Materials of Santa Clara, Calif.), Xerogel, Aerogel, amorphous fluorinated carbon, and/or other materials.

The photoresist layer 122 may be formed over the dielectric layer 114 using a process such as spin-on coating. For example, a photoresist solution may be dispensed onto the surface of the dielectric layer 114, and the device 100 may be spun rapidly until the photoresist solution is almost dry. It is understood that the photoresist layer 122 may be a chemically amplified resist that employs acid catalysis. In that case, the photoresist layer 122 may be formulated by dissolving an acid sensitive polymer in a casting solution.

The PAG layer 120 is formed above the photoresist layer 122. The PAG layer 120 includes at least one PAG that includes one or more components such as aryl onium salts (triarylsulfoniums or diaryliodoniums), thiophene, or any other suitable component. The PAG may be combined with any of a variety of materials. For example, the PAG may be dissolved in a solvent, such as butanol, water, and/or any other suitable solvent. In another example, the PAG may be blended into one or more polymers, such as acrylate, methacrylate, para-hydroxy styrene, and/or any other suitable polymer, which may be developable or non-developable. In some embodiments, the PAG may include one or more ionic and/or non-ionic components. The PAG layer 120 may be deposited over the dielectric layer 114 using a variety of techniques, such as spin-on coating, PVD, chemical CVD, and/or other processes. For example, the PAG layer 120 may be sprayed over the dielectric layer 114. It is understood that the method used to form the PAG layer 120 may vary depending on the material(s) comprising the PAG layer 120.

In some embodiments, the PAG layer 120 may form a top anti-reflective coating (TARC) layer. As a TARC layer, the PAG layer 120 may be translucent or transparent, and may function similarly to an index-matched BARC layer (as described above).

Following the deposition of the PAG layer 120, the partial semiconductor device 100 may undergo a soft-bake (also known as pre-bake or post-apply bake) process to prepare for the next step of exposure.

Referring to FIG. 3b, the partial semiconductor device 100 is exposed to radiation during an exposure process to create a latent image in the photoresist layer 122. In the present example, the exposure results in an undercut profile or a T-top profile (indicated by reference numeral 123) in the resist layer 122. In addition to exposing the tapered area 123, the exposing process exposes a portion (indicated by reference numeral 121) of the PAG layer 120 and generates photo acid therein. It is understood that the actual dimensions of the portion 121 may vary from those illustrated.

Referring to FIG. 3c, in furtherance of the example, a post-exposure baking process is performed on the device 100 after the exposure process. During the post-exposure baking process, the photo acids generated from the PAG layer portion 121 are diffused thorough the photoresist (particularly in photoresist portions 124 and 125) and react with the photoresist to de-protect the photoresist (e.g., to remove the photoresist's protecting group) through a catalytic reaction initiated by the thermal baking process.

Referring to FIG. 2d, after the post-exposure baking, the baked device 100 undergoes a development process to develop the photoresist layer 122. Due to the reaction caused by the diffused acids from the PAG layer portion 121, the development process results in a photoresist profile 126 in which the undercut sidewalls of FIG. 3b are minimized or eliminated. Accordingly, the PAG layer 120 results in an improved DOF. In one example, the enhanced DOF may be approximately 0.15 (as opposed to 0.05 in the absence of the PAG layer 120).

Although additional manufacturing steps may be performed after those illustrated in FIG. 3d, such steps are similar or identical to those known in the art, and they will not be further described herein.

It is understood that many variations of the above embodiments are contemplated herein. For example, the PAG layer 120 of FIGS. 2a-2d may include two layers: a first layer that includes at least one PAG dissolved in a solvent and sprayed over the substrate 110, and a second layer that includes a BARC layer containing at least one PAG. In another example, the PAG layer 120 of FIGS. 3a-3d may include two layers: a first layer that includes at least one PAG dissolved in a solvent and sprayed over the photoresist layer 120, and a second layer that includes a TARC layer containing at least one PAG. In still another example, the device 100 may include both a PAG layer below the photoresist layer 120 (as illustrated in FIGS. 2a-2d) and a PAG layer above the photoresist layer 120 (as illustrated in FIGS. 3a-3d). In yet another example, the device 100 may include two PAG layers (one above and one below the photoresist layer 120), with at least one of the PAG layers including multiple layers (e.g., a BARC or TARC layer).

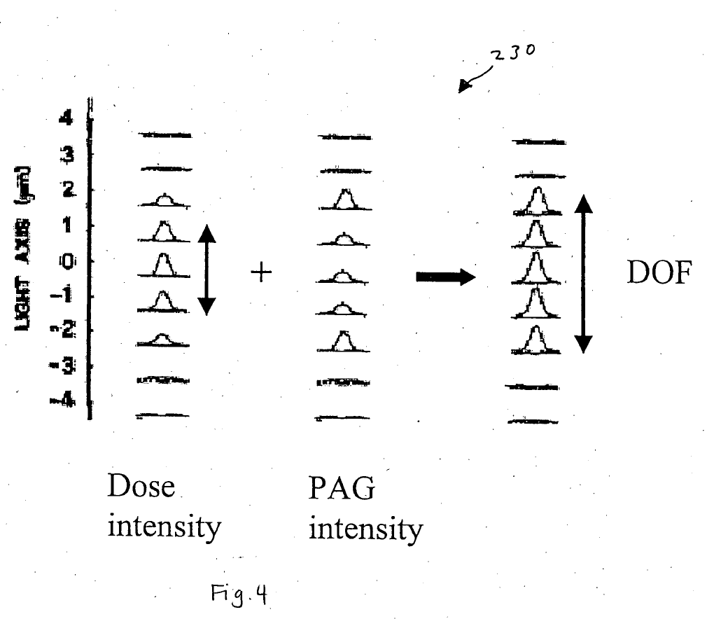

Referring now to FIG. 4, a chart 230 illustrates various exemplary combinations of dose intensity and PAG intensity with respect to DOF. The left axis, which represents light (in μm), illustrates exemplary magnitudes for each dose intensity. As illustrated by the chart 230, the PAG intensity (e.g., the amount of PAG needed) increases as the dose intensity deviates from the ideal (represented by 0). It is understood that, at a certain level of dose intensity, further increases in the PAG intensity may fail to produce additional DOF improvements.

Although only a few exemplary embodiments of this disclosure have been described in details above, those skilled in the art will readily appreciate that many modifications are possible in the exemplary embodiments without materially departing from the novel teachings and advantages of this disclosure. Also, features illustrated and discussed above with respect to some embodiments can be combined with features illustrated and discussed above with respect to other embodiments. Accordingly, all such modifications are intended to be included within the scope of this disclosure.

What is claimed is:

1. A method for manufacturing a semiconductor device, comprising:
providing a substrate;
forming a first photo acid generator (PAG) layer over the substrate, wherein the first PAG layer includes at least one PAG; and
forming a photoresist layer over the first PAG layer.

2. The method of claim 1 wherein the first PAG layer is a bottom anti-reflective coating (BARC) layer.

3. The method of claim 1 further comprising:
masking the photoresist layer;
exposing the photoresist layer and the first PAG layer as defined by the masking;
performing a thermal baking process on the exposed photoresist layer and the first PAG layer; and
developing the exposed photoresist layer.

4. The method of claim 1 further comprising forming a second PAG layer over the photoresist layer, wherein the second PAG layer includes at least one PAG.

5. The method of claim 4 wherein the second PAG layer is a top anti-reflective coating (TARC) layer.

6. The method of claim 4 further comprising:
masking the second PAG layer;
exposing the second PAG layer, the photoresist layer, and the first PAG layer as defined by the masking;
performing a thermal baking process on the second PAG layer, the photoresist layer, and the first PAG layer; and
developing the exposed photoresist layer.

7. The method of claim 6 further comprising removing the second PAG layer prior to the developing.

8. The method of claim 1 wherein the first PAG layer comprises the at least one PAG dissolved in a solvent.

9. The method of claim 1 wherein the first PAG layer comprises the at least one PAG blended into a polymer.

10. The method of claim 9 wherein the polymer is developable.

11. The method of claim 9 wherein the polymer is non-developable.

12. The method of claim 1 wherein the at least one PAG comprises an ionic component.

13. The method of claim 1 wherein the at least one PAG comprises a non-ionic component.

14. A method for manufacturing a semiconductor device, comprising:
providing a substrate;
forming a photoresist layer over the substrate; and
forming a photo acid generator (PAG) layer over the photoresist layer, wherein the PAG layer includes at least one PAG.

15. The method of claim 14 wherein the PAG layer is a top anti-reflective coating (TARC) layer.

16. The method of claim 14 further comprising:
masking the PAG layer;
exposing the PAG layer and the photoresist layer as defined by the masking;
performing a thermal baking process on the exposed PAG layer and the photoresist layer; and
developing the exposed photoresist layer.

17. The method of claim 16 further comprising removing the PAG layer prior to the developing.

18. The method of claim 14 wherein the PAG layer comprises the at least one PAG dissolved in a solvent.

19. The method of claim 14 wherein the PAG layer comprises the at least one PAG blended into a polymer.

20. The method of claim 19 wherein the polymer is developable.

21. The method of claim 14 wherein the at least one PAG comprises an ionic component.

22. The method of claim 14 wherein the at least one PAG comprises a non-ionic component.

23. A method for manufacturing a semiconductor device, comprising:
providing a substrate; and
forming an anti-reflection coating (ARC) layer over the substrate, wherein the ARC layer includes a photo acid generator (PAG).

24. The method of claim 24 further comprising forming a layer of photoresist over the ARC layer.

25. The method of claim 25 further comprising forming a photo acid generator (PAG) layer over the photoresist layer, wherein the PAG layer includes at least one PAG.

26. The method of claim 24 further comprising forming a layer of photoresist over the substrate prior to forming the ARC layer.
